(19) United States
(12) Patent Application Publication
(10) Pub. No.: US 2003/0186528 A1
(43) Pub. Date: Oct. 2, 2003

(54) Method for producing tin/lead alloy balls for packaging semiconductors

(76) Inventor: Chih-Heng Chen, Taipei (TW)

Correspondence Address: Keith Kline, PRO-TECHTOR INTERNATIONAL SERVICES, 20775 Norada Court, Saratoga, CA, 95070-3018, US

(21) Appl. No.: 10/114,084

(22) Filed: Apr. 1, 2002

(51) Int. Cl. H01L 21/44

(52) U.S. Cl. 438/613; 438/612

(57) ABSTRACT

A method for producing tin/lead alloy balls for packaging semiconductors comprises: choosing a tin/lead alloy stick having a required composition and diameter according to a size and composition of tin/lead alloy balls to be produced; cutting the tin/lead alloy stick into tin/lead particles each having a weight the same as a tin/lead alloy ball to be produced; distributing the tin/lead particles in a high-temperature liquid in a manner that each tin/lead particle softens when it reaches an upper level of the high-temperature liquid to thereby cluster into a tin/lead alloy ball and that the temperature of the tin/lead alloy ball gradually lowers when it sinks in the high-temperature liquid; shaping the temperature-decreasing tin/lead alloy balls at normal temperature; cleaning the shaped tin/lead alloy balls; sorting the cleaned tin/lead alloy balls according to circularity and diameter tolerance; and packing the sorted tin/lead alloy balls.

### BACKGROUND OF THE INVENTION

1. Field of the Invention

The present invention relates to a method for producing tin/lead alloy balls for packaging semiconductors. In particular, the present invention relates to a method for producing tin/lead alloy balls for packaging ball-grid array integrated circuits.

2. Description of the Related Art

Currently, the semiconductors of large scale integrated circuits adopt ball-grid array packaging/soldering the basic elements of which are tin/lead alloy balls (the so-called “tin ball”). Thus, the tin/lead alloy balls are the decisive factor to the packaging/soldering quality of the semiconductors.

The tin/lead alloy balls are typically formed by melting tin/lead lumps and then forming tin/lead alloy balls from the molten tin/lead by pressurized spraying. As illustrated in FIG. 1 of the drawings, the tin/lead lump lumps are melted at high temperature into liquid state, which is then pressurized and sprayed. The temperature of the discharged tin/lead liquid is lowered and thus shaped into balls during the travel in the air under the action of gravity. After sorting according to the required size and circularity, the formed balls are packed.

The tin/lead alloy balls thus produced have a wide range of sizes and thus have a poor production rate. In addition, the dramatic lowering in the temperature during formation of the balls results in structural change in the tin and lead such that the balls tend to have cracks on the surfaces thereof. As a result, fluorescent paint must be applied to improve the poor smoothness in the surfaces of the balls. Additional labor, material, and time are required. Further, the balls tend to be oxidized in the air.

### SUMMARY OF THE INVENTION

An object of the present invention is to provide a method for producing tin/lead alloy balls for packaging semiconductors, wherein the produced tin/lead alloy balls are uniform in size to thereby improve the circularity and production rate. In addition, the surfaces of the balls are smooth without any crack or scratch and are oxidization resistant to meet practical needs.

The above-mentioned object is achieved by a method for producing tin/lead alloy balls for packaging semiconductors in accordance with the present invention. The method comprises the steps of: (a) choosing a tin/lead alloy stick having a required composition and diameter according to a size and composition of tin/lead alloy balls to be produced; (b) cutting the tin/lead alloy stick into tin/lead particles each having a weight the same as a tin/lead alloy ball to be produced; (c) distributing the tin/lead particles in a high-temperature liquid in a manner that each tin/lead particle softens when it reaches an upper level of the high-temperature liquid to thereby cluster into a tin/lead alloy ball and that the temperature of the tin/lead alloy ball gradually lowers when it sinks in the high-temperature liquid; (d) shaping the temperature-decreasing tin/lead alloy balls at normal temperature; (e) cleaning the shaped tin/lead alloy balls; (f) sorting the cleaned tin/lead alloy balls according to circularity and diameter tolerance; and (g) packing the sorted tin/lead alloy balls.

Other objects, advantages, and novel features of the invention will become more apparent from the following detailed description when taken in conjunction with the accompanying drawings.

### BRIEF DESCRIPTION OF THE DRAWINGS

FIG. 1 is a block diagram illustration production of tin/lead alloy balls according to a conventional method.

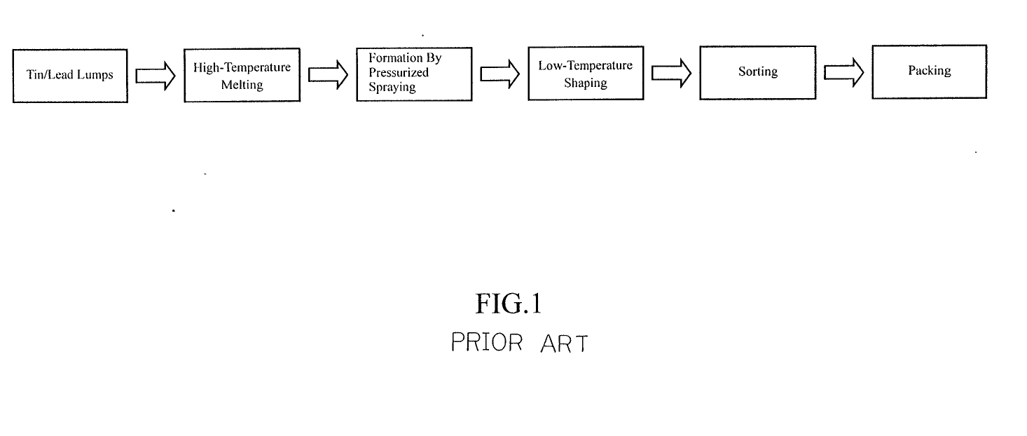

FIG. 2 is a block diagram illustrating an embodiment of production of tin/lead alloy balls by a method in accordance with the present invention.

FIG. 3 is a perspective view, in an enlarged scale, illustrating preparation of tin/lead particles.

FIG. 4 is a sectional view illustrating formation of the tin/lead balls from the particles in FIG. 3.

FIG. 5 is a sectional view illustrating shaping of the tin/lead balls in FIG. 4.

FIG. 6 is a block diagram illustrating another embodiment of production of tin/lead alloy balls by the method in accordance with the present invention.

FIG. 7 is a block diagram illustrating a further embodiment of production of tin/lead alloy balls by the method in accordance with the present invention.

### DETAILED DESCRIPTION OF THE PREFERRED EMBODIMENTS

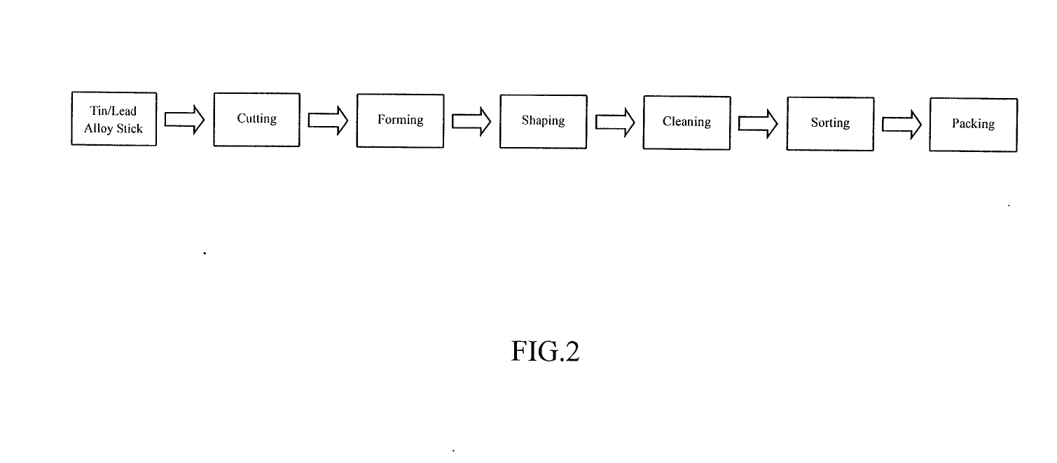

Referring to FIGS. 2 through 6 and initially to FIG. 2, a method for producing tin/lead alloy balls for packaging semiconductors in accordance with the present invention comprises the steps of: (a) choosing a tin/lead alloy stick having a required composition and diameter according to a size and composition of tin/lead alloy balls to be produced; (b) cutting the tin/lead alloy stick into tin/lead particles each having a weight the same as a tin/lead alloy ball to be produced; (c) distributing the tin/lead particles in a high-temperature liquid in a manner that each tin/lead particle softens when it reaches an upper level of the high-temperature liquid to thereby cluster into a tin/lead alloy ball and that the temperature of the tin/lead alloy ball gradually lowers when it sinks in the high-temperature liquid; (d) shaping the temperature-decreasing tin/lead alloy balls at normal temperature; (e) cleaning the shaped tin/lead alloy balls; (f) sorting the cleaned tin/lead alloy balls according to circularity and diameter tolerance; and (g) packing the sorted tin/lead alloy balls.

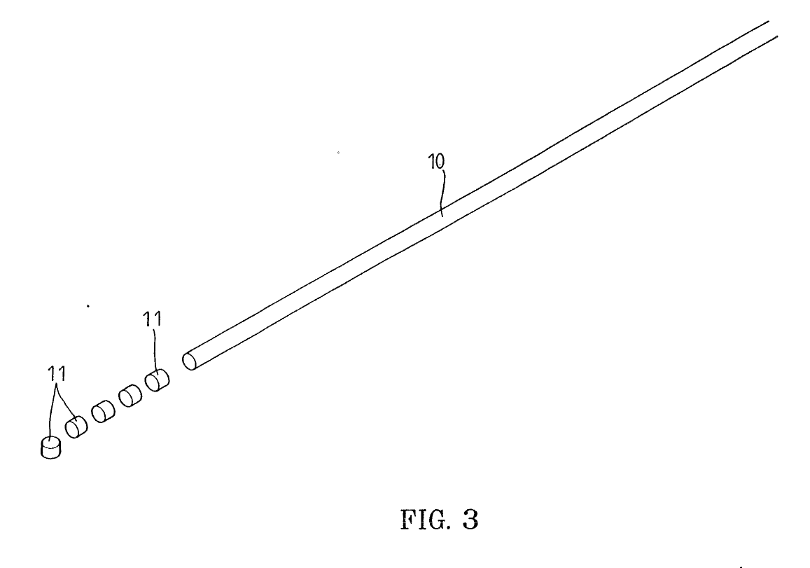

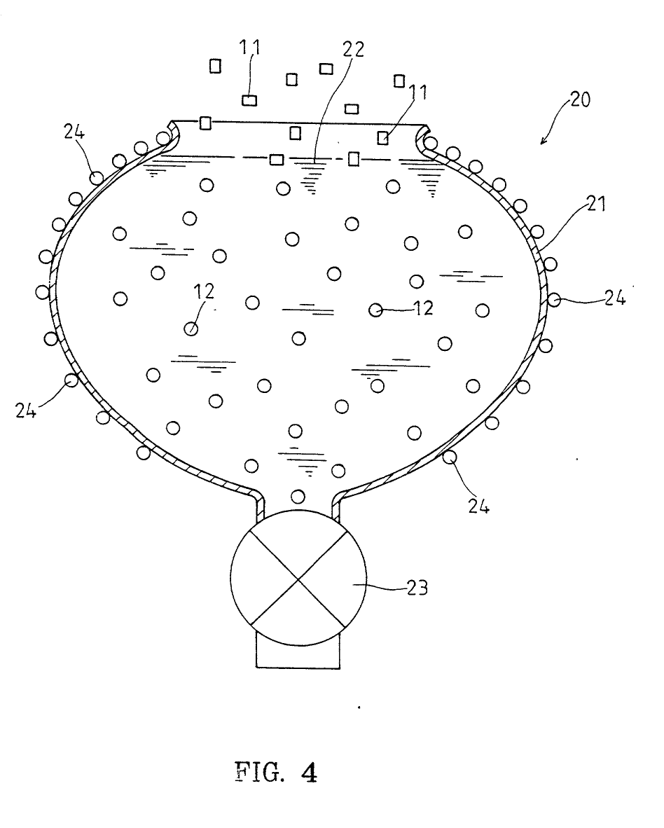

More specifically, referring to FIG. 2, the first step of the method for producing tin/lead alloy balls for packaging semiconductors in accordance with the present invention is choosing a tin/lead alloy stick 10 (FIG. 3) having a required composition and diameter according to the size and composition of tin/lead alloy balls to be produced. The tin/lead alloy stick 10 is then cut into tin/lead particles 11 (FIG. 3) each having a weight the same as a tin/lead alloy ball to be produced. Next, the tin/lead particles 11 are shaped into balls by a ball-forming device 20. As illustrated in FIG. 4, the ball-forming device 20 comprises a container 21 receiving a heat-conducting liquid 22 therein and an electric heater 24 outside the container 21. The upper level of the liquid 22 has the highest temperature enough for softening the tin/lead alloy that has a softening temperature of about 179˜183° C. The temperature of the liquid 22 gradually decreases from the upper level to a lower level of the liquid 22. The tin/lead particles 11 are dropped into and distributed in the liquid 22 as free-falling bodies such that each tin/lead particle 11 softens when it reaches the upper level of the high-temperature liquid 22 to thereby cluster into a tin/lead alloy ball 12 and that the temperature of the tin/lead alloy ball 12 gradually lowers when it sinks in the high-temperature liquid 22.

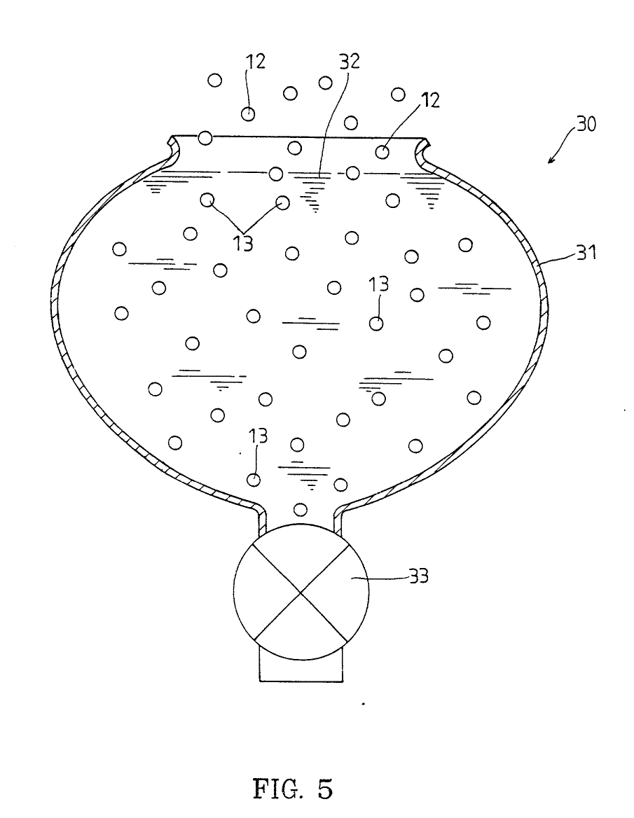

The tin/lead alloy balls 12 are discharged from a discharging valve 23 of the ball-forming device 20 into a normal-temperature liquid 32 contained in a container 31 of a ball-shaping device 30. Each tin/lead ball 12 takes shape of a ball (now designated by 13) in this step, best shown in FIG. 5. The shaped balls 13 are discharged via a discharging valve 33 of the ball-shaping device 30 for subsequent cleaning to remove contaminants and oxides. Finally, the cleaned tin/lead alloy balls are sorted according to circularity and diameter tolerance and then packed in bottles in an environment full of nitrogen after measurement by a precise balance.

In this embodiment, since the tin/lead stick 10 is chosen according to the size, weight, and composition of the tin/lead alloy balls to be produced, and the tin/lead stick 10 is cut to provide particles 11 that are subsequently formed and shaped into balls in the ball-forming device 20 and the ball-shaping device 30, tin/lead alloy balls of uniform sizes can be produced to thereby improve the circularity and production rate. In addition, the surfaces of the balls are smooth without scratches and are oxidization resistant without adversely affecting the physical structure of the tin/lead alloy.

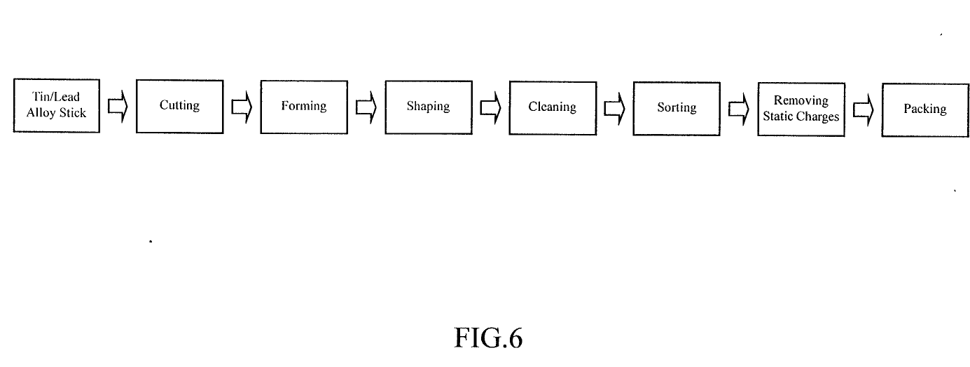

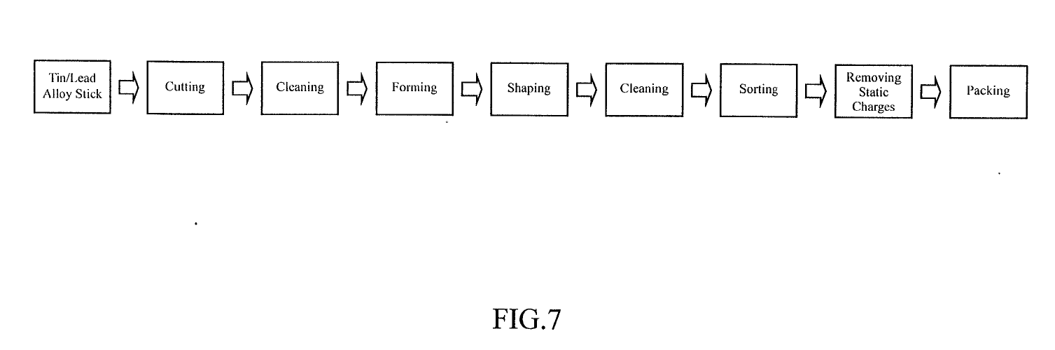

In another embodiment, as illustrated in FIG. 6, a static charge remover can be applied after cleaning the balls 13 to thereby remove the static charges on the balls 13. In a further embodiment, as illustrated in FIG. 7, a cleaning step can be added between the cutting step and forming step to remove contaminants and oxides.

Although the invention has been explained in relation to its preferred embodiment, it is to be understood that many other possible modifications and variations can be made without departing from the scope of the invention as hereinafter claimed.

What is claimed is:

1. A method for producing tin/lead alloy balls for packaging semiconductors, the method comprising the steps of:
(a) choosing a tin/lead alloy stick having a required composition and diameter according to a size and composition of tin/lead alloy balls to be produced;
(b) cutting the tin/lead alloy stick into tin/lead particles each having a weight the same as a tin/lead alloy ball to be produced;
(c) distributing the tin/lead particles in a high-temperature liquid in a manner that each said tin/lead particle softens when it reaches an upper level of the high-temperature liquid to thereby cluster into a tin/lead alloy ball and that the temperature of the tin/lead alloy ball gradually lowers when it sinks in the high-temperature liquid;
(d) shaping the temperature-decreasing tin/lead alloy balls at normal temperature;
(e) cleaning the shaped tin/lead alloy balls;
(f) sorting the cleaned tin/lead alloy balls according to circularity and diameter tolerance; and
(g) packing the sorted tin/lead alloy balls.

2. The method as claimed in claim 1, wherein the shaping step (d) at normal temperature is proceeded in a liquid.

3. The method as claimed in claim 1, further comprising a step of removing static charges from the balls by a static charge remover after step (f).

4. The method as claimed in claim 1, wherein the tin/lead alloy balls are measured by a precise balance and then packed in bottles under an environment full of nitrogen.
